(19) United States
(12) Patent Application Publication
(10) Pub. No.: US 2026/0190865 A1
(43) Pub. Date: Jul. 2, 2026

(54) ELECTRONIC COMPONENT INTEGRATED PHASE CHANGE MATERIAL SWITCH

(71) Applicant: Taiwan Semiconductor Manufacturing Company, Ltd., Hsinchu (TW)

(72) Inventors: Kuo-Pin Chang, Zhubei City (TW); Ching-En Chen, Chiayi City (TW); Hung-Ju Li, Hsinchu City (TW); Yu-Wei Ting, Taipei City (TW); Kuo-Ching Huang, Hsinchu City (TW)

(73) Assignee: Taiwan Semiconductor Manufacturing Company, Ltd., Hsinchu (TW)

(21) Appl. No.: 19/008,582

(22) Filed: Jan. 2, 2025

(51) Int. Cl. H10N 39/00; H01P 1/15

(52) U.S. Cl. CPC H10N 39/00; H01P 1/15

(57) ABSTRACT

An electronic component includes a passive device, a phase change material (PCM) switch, and an electrically insulating layer. The PCM switch is electrically connected to the passive device. The PCM switch includes a phase change material (PCM) layer, a first electrode contacting the PCM layer, a second electrode contacting the PCM layer, and a resistive heating element configured to heat a portion of the PCM layer. The electrically insulating layer is disposed between and thermally coupled to the PCM layer and the resistive heating element.

### BACKGROUND

Advantages of PCM switches include their immunity to interference by electromagnetic radiation, relatively fast switching times, and ability to maintain their switching state (e.g., an “on” state or an “off” state) without consuming electrical power. As such, one or more phase change material (PCM) switches are integrated in an electronic component for various applications.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates example diagrams of phases of a PCM that change in response to different temperature profiles, in accordance with some embodiments of the disclosure.

FIG. 2A illustrates a portion of perspective structure view of an example PCM switch, in accordance with some embodiments of the disclosure.

FIG. 2B illustrates a portion of perspective structure view of an example PCM switch, in accordance with some embodiments of the disclosure.

FIG. 2C illustrates a portion of perspective structure view of an example PCM switch, in accordance with some embodiments of the disclosure.

FIG. 3A illustrates a portion of a circuit diagram of an electronic component, in accordance with an embodiment of the disclosure.

FIG. 3B illustrates a portion of perspective structure view of an electronic component, in accordance with an embodiment of the disclosure.

FIG. 4A illustrates a portion of a circuit diagram of an electronic component, in accordance with an embodiment of the disclosure.

FIGS. 4B, 4C and 4D illustrate a portion of perspective structure views of an electronic component, in accordance with an embodiment of the disclosure.

FIG. 5A illustrates a portion of a circuit diagram of an electronic component, in accordance with an embodiment of the disclosure.

FIG. 5B illustrates a portion of perspective structure view of an electronic component, in accordance with an embodiment of the disclosure.

FIG. 5C illustrates an operation diagram of an electronic component, in accordance with an embodiment of the disclosure.

FIG. 6 illustrates a portion of a circuit diagram of an electronic component, in accordance with an embodiment of the disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the component in use or operation in addition to the orientation depicted in the figures. The apparatus may be otherwise oriented (rotated 90 degrees or at other orientations) and the spatially relative descriptors used herein may likewise be interpreted accordingly.

It will be understood that, although the terms “first”, “second”, “third” and the like, may be used herein to describe various elements, these elements should not be limited by these terms. These terms are only used to distinguish one element from another. For example, a first element may be referred to as a second element, and similarly, a second element may be referred to as a first element without departing from the scope of protection of the inventive concept.

Some embodiments of the disclosure are described. Additional operations may be provided before, during, and after the processing of the stages of these embodiments described. Some of the stages described may be replaced or deleted for different embodiments. In different embodiments, some of the features described herein may be replaced or deleted, and additional features may be added. Although some embodiments are discussed as performing operations in a particular order, these operations may be performed in another logical order.

Radio frequency (RF) switches or microwave switches (sometimes may be referred as “RF components” or “microwave components”) are components that transmit high frequency signals through a transmission path. In an embodiment, a RF or microwave switch has an appropriate application, for example, in a microwave test system to route signals between an equipment and a device under test (DUT). In an embodiment, a RF or microwave switch has an appropriate application, for example, in wireless communications.

Various embodiments of the disclosure include one or more phase change material (PCM) switch (e.g., a PCM switch 100 as described below or as shown below). The PCM switch could be integrated with one or more various semiconductor components, such as a radio frequency component, a varactor capacitor (e.g., a variable capacitor), an inductor, or another semiconductor component forming by a semiconductor process.

In the disclosure, the “phase change material” could be referred to a material that has at least two different phases that provide different resistivities. The different phases may include a crystalline phase with a relatively high resistivity and a crystalline phase with a relatively low resistivity. The reversible transition between the aforementioned amorphous and crystalline phases could be induced by controlling the time versus temperature thermal profile within the phase change material.

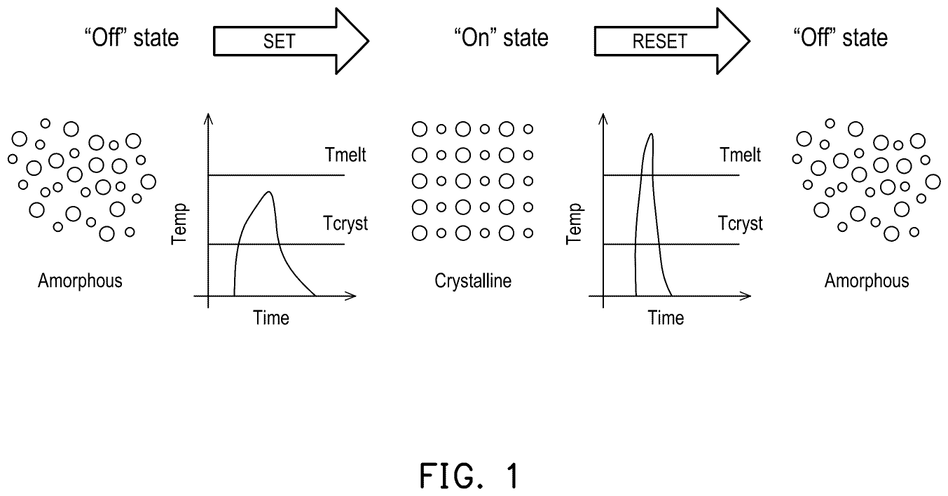

For example, as shown in FIG. 1, in order to induce a transition of the phase change material from a relatively high-resistivity crystalline phase to a relatively low-resistivity crystalline phase, a current pulse through a resistive heating element may have a relatively longer pulse width with a longer pulse falling time that is configured to heat the phase change material to a temperature above its crystallization temperature (Tcryst), but below its melting temperature (Tmelt), over a time period sufficient to induce crystal nucleation in the material. The comparatively long falling time of the current pulse promotes crystal growth as the phase change material cools at a relatively slower rate.

For example, as shown in FIG. 1, in order to induce a transition of the phase change material from a relatively low-resistivity crystalline phase to a relatively high-resistivity crystalline phase, a current pulse through the resistive heating element may have a relatively short pulse width with a short falling time that is configured to quickly heat the phase change material to a temperature above its melting temperature (Tmelt), causing the material to transition from an ordered crystalline low-resistivity phase to a disordered amorphous high-resistivity phase. The short falling time of the pulse promotes rapid quenching and inhibits re-crystallization of the material as it cools.

In various embodiments of the disclosure, the PCM switch may include at least one resistive heating element thermally coupled to the phase change material and configured to selectively heat the phase change material via application of a current through the resistive heating element. For more example, the PCM switch may further include a heat dissipation element thermally coupled to the phase change material and/or the resistive heating element, and configured to dissipate the thermal energy of the heated phase change material and/or the resistive heating element. In an embodiment, a suitable phase change material for being applicated in a semiconductor component or a semiconductor process (e.g., an atomic layer deposition (ALD) process, a high density plasma chemical vapor deposition (HDP-CVD) process, or a flowable chemical vapor deposition (FCVD) process) may include germanium telluride (GeTe), antimony telluride (SbTe), germanium-antimony-tellurium (GeSbTe or GST; for example, such as Ge₂Sb₂Te₅), vanadium dioxide (VO₂), doped thereof (e.g., In-doped or Sb-doped; e.g., doped GeTe, doped GST), or combinations thereof. In an embodiment, a material of the resistive heating element may include tungsten (W), tungsten nitride (WN), titanium nitride (TiN), metal silicide (e.g., nickel silicide (NiSi)), metal alloy (e.g., aluminum copper alloy (AlCu)), combinations or stacking thereabove.

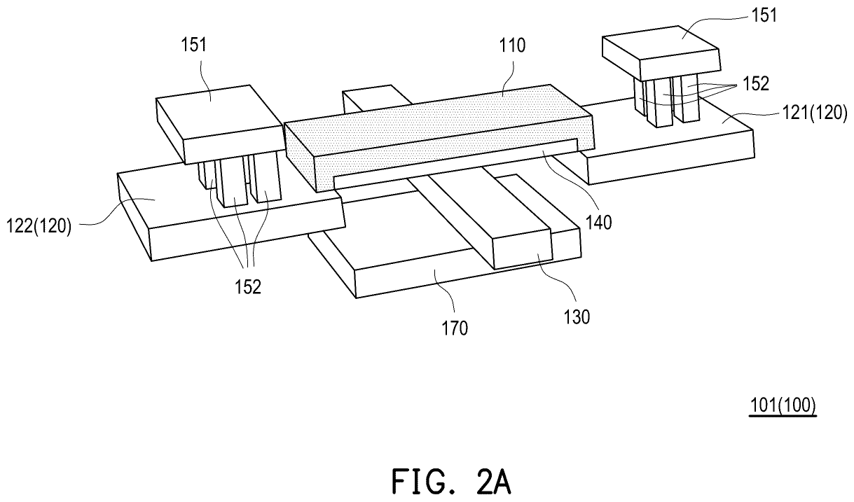

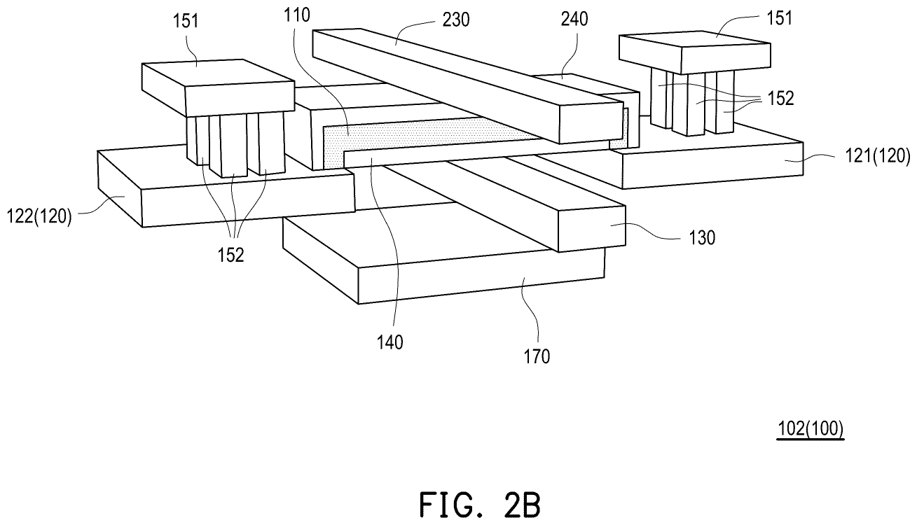

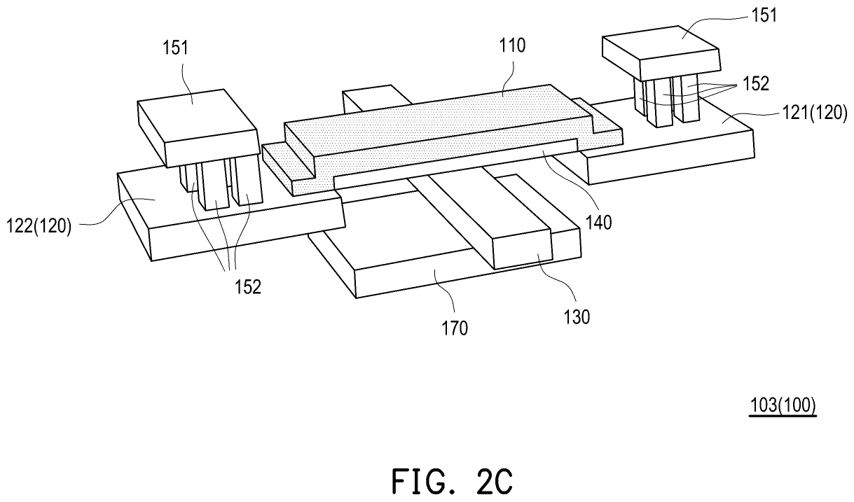

As shown in FIG. 2A, a PCM switch 101 (a type of the PCM switch 100) may include a phase change material 110 disposed within a signal transmission path between at least two of opposite electrodes 120 (e.g., between the electrode 121 and the electrode 122). The resistive heating element 130 could extend across the phase change material 110 in a direction transverse to the signal transmission path, and an electrically insulating layer 140 could be disposed between the resistive heating element 130 and the phase change material 110. While the phase change material 110 is in a low resistivity crystalline phase, the PCM switch 101 could be in an “on” state, allowing signals to be transmitted across the phase change material 110 between the opposite electrodes 120. However, when the phase change material 110 is in a high-resistivity crystalline phase along a portion of the signal transmission path, the PCM switch 101 could be in an “off” state, such that signal transmission between the opposite electrodes 120 is blocked. The PCM switch 101 could be switched (e.g., programmed) between an “on” state and an “off” state by the selective application of current pulses with different pulse widths and fall times as described to the resistive heating element 130. The portion of the phase change material 110 that switches between the low resistivity crystalline phase and the high resistivity crystalline phase may be referred to as the active region of the phase change material 110.

In an embodiment, the electrodes 120 and the resistive heating element 130 are electrically separated (or further structurally separated) from each other by a corresponding insulating layer (not shown). In an embodiment, the electrodes 120 and the resistive heating element 130 electrically separated from each other are different portion of a same conductive layer (e.g., at the same level, having the same thickness, and having the same material substantially), but the disclosure is not limited thereto. In an embodiment, the electrodes 120 and the resistive heating element 130 are at the same level and/or have the same thickness substantially, but are of different materials from each other. In an embodiment, a conductivity of the electrodes 120 is higher than a conductivity of the resistive heating element 130. In an embodiment, a material of the electrodes 120 may include tungsten (W), copper (Cu), metal alloy (e.g., aluminum copper alloy (AlCu)), metal silicide (e.g., nickel silicide (NiSi)), combinations or stacking thereabove.

For a switch (e.g., the PCM switch 100) used in radio-frequency (RF) applications, relevant factors for evaluating switch performance may include insertion loss, isolation and power handling. In general, low insertion loss and high isolation are desirable characteristics for RF switches. For PCM switches (e.g., the PCM switch 100), insertion loss is related to the resistivity across the phase change material 110 when the switch is in the “On” state (e.g., R_{ON}), while high isolation is inversely related to the capacitance of the switch while in the “Off” state (e.g., C_{OFF}). A figure of merit (FOM) used to characterize PCM switch 100 performance may be inversely proportional to the product R_{ON}*C_{OFF}. For example, one FOM that is used to characterize switch performance is about 1/(2πR_{ON}C_{OFF}), where a higher FOM value equals better switch performance. Thus, switch performance may be improved by reducing the R_{ON} characteristics, the C_{OFF} characteristics, or both, in a PCM switch 100.

An examplify design for PCM switches (e.g., the PCM switch 100) may be not optimally efficient because much of the thermal energy generated by the resistive heating element 130 is spread laterally by the layer of electrically-insulating and thermally-conductive material located between the resistive heating element 130 and the phase change material 110. Accordingly, during a switching operation, the peak temperature in the active region of the phase change material 110 is relatively low, and a high bias voltage across the resistive heating element 130 is needed in order to provide sufficient heating to induce the desired phase change in the active region of the phase change material 110. Moreover, because much of the thermal energy is diffused laterally, the active region may be relatively large, and portions of the phase change material 110 outside of the active region may inadvertently become “soft programmed” to have an intermediate resistivity state that is between the high-resistivity “Off” state and the low-resistivity “On” state of the PCM switch 100. This may result in undesired parasitic resistance across the phase change material 110 that may increase the RON characteristics of the PCM switch 100. Further, the electrically-insulating and thermally-conductive material located between the resistive heating element 130 and the phase change material 110 is typically a high-k dielectric material (e.g., a material of the electrically insulating layer 140) that may contribute to a high C_{OFF} characteristic of the PCM switch 100.

In an embodiment, the electrically insulating layer 140 may have high thermal conductivity and good electrical isolation and may be formed of aluminum nitride (AlN), silicon carbide (SiC), silicon nitride (SiN), diamond or a suitable insulating 2D material (e.g., hexagonal boron nitride (h-BN, graphitic BN)) having properties of electrically insulating between the resistive heating element 130 and the phase change material 110, and allowing heat from the resistive heating element 130 passing therethrough to the phase change material 110. In an embodiment, a thermal conductivity of the material of the electrically insulating layer 140 is higher than a thermal conductivity of the material of the insulating layer (not shown) deposed between each of the electrodes 120 and the resistive heating element 130. In an embodiment, the electrically insulating layer 140 may be referred as a thermal boundary resistance (TBR) layer, but the disclosure is not limited thereto.

In an embodiment, at least one of the electrodes 120 could be electrically connected to a corresponding circuit 151 by one or more corresponding conductor. For example, an electrode 120 could be electrically connected to a circuit 151 by one or more corresponding conductive vias 152. In an embodiment, the circuits 151 and/or the conductive vias 152 are a portion of interconnectors. In an embodiment, the interconnectors are formed by an appropriate semiconductor process (e.g., a back-end of line (BEOL) process).

In an embodiment, a heat dissipation element 170 is configured, such that the resistive heating element 130 is disposed between the phase change material 110 and the heat dissipation element 170.

In an embodiment, a material of the heat dissipation element 170 includes metal (e.g., Cu), and an electrically insulating layer (not shown) could be disposed between the resistive heating element 130 and the electrically conductive heat dissipation element (e.g., a type of the heat dissipation element 170). In an embodiment, the electrically insulating layer (in any; not shown) disposed between the resistive heating element 130 and the electrically conductive heat dissipation element may have high thermal conductivity and good electrical isolation.

In an embodiment, a material of the heat dissipation element 170 is electrically insulating and has high thermal conductivity, and the electrically insulating heat dissipation element (e.g., a type of the heat dissipation element 170) could be directly or indirectly contacted with the resistive heating element 130.

As shown in FIG. 2B, a PCM switch 102 (a type of the PCM switch 100) may include a phase change material 110 disposed within a signal transmission path between at least two of opposite electrodes 120 (e.g., between the electrode 121 and the electrode 122). The resistive heating elements 130, 230 could extend across the phase change material 110 in a direction transverse to the signal transmission path. The phase change material 110 is disposed between the resistive heating element 130 and the resistive heating element 230. An electrically insulating layer 140 could be disposed between the resistive heating element 130 and the phase change material 110, and an electrically insulating layer 240 could be disposed between the resistive heating element 230 and the phase change material 110.

In an embodiment, a material of the resistive heating element 230 may be substantially the same or similar to the material of the resistive heating element 130. In an embodiment, a material of the electrically insulating layer 240 may be substantially the same or similar to the material of the electrically insulating layer 140.

In an embodiment, the resistive heating elements 130, 230 could be electrically connected to each. For example, the resistive heating elements 130, 230 could be electrically connected in series or parallel through one or more corresponding circuits (not shown; may be similar to the circuit 151) and/or one or more corresponding conductive vias (not shown; may be similar to the conductive via 152).

In an embodiment, the circuits 151 and the resistive heating element 230 are electrically separated (or further structurally separated) from each other by a corresponding insulating layer (not shown). In an embodiment, the circuits 151 and the resistive heating element 230 electrically separated from each other are different portions of a same conductive layer, but the disclosure is not limited thereto. In an embodiment, the circuits 151 and the resistive heating element 230 are at the same level and/or have the same thickness substantially, but are of different materials from each other. In an embodiment, a conductivity of the circuits 151 is higher than a conductivity of the resistive heating element 230.

As shown in FIG. 2C, a PCM switch 103 (a type of the PCM switch 100) may include a phase change material 110 disposed within a signal transmission path between at least two of opposite electrodes 120 (e.g., between the electrode 121 and the electrode 122). A portion of the phase change material 110 may extend away from the landing portion of the electrode 120, for example, further toward the corresponding conductive via 152.

In the subsequent various embodiments, the integration and application of the PCM switch 100 and other components are descripted and illustrated. It is worth noting that in the embodiments described or illustrated subsequently, the PCM switch 101 may be used as an example, so the same or similar symbols are labeled and descriptions are omitted. However, one or more subsequent PCM switches 101 may be replaced with one or more subsequent PCM switches 102, 103.

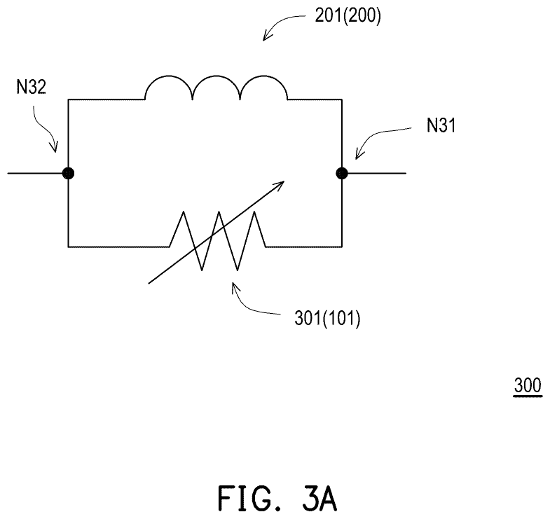

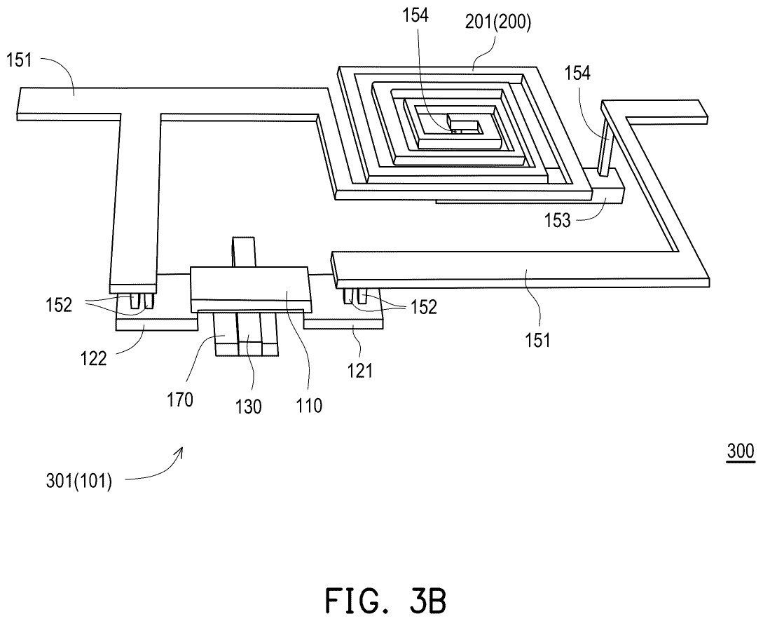

FIG. 3A illustrates a portion of a circuit diagram of an electronic component, in accordance with an embodiment of the disclosure. FIG. 3B illustrates a portion of perspective structure view of an electronic component, in accordance with an embodiment of the disclosure. For example, the structure as shown in FIG. 3B may have an equivalent circuit as shown in FIG. 3A, and/or the circuit as shown in FIG. 3A may have a corresponding structure as shown in FIG. 3B. As such, for the purpose of simplicity and/or clarity, the electronic components as shown in FIGS. 3A and 3B are labeled with a same symbol.

As shown in FIGS. 3A and 3B, the electronic component 300 includes at least one PCM switch 101 (e.g., the PCM switch 301) and at least one an inductor 200 (e.g., the inductor 201; a type of a passive device). The PCM switch 301 (a type of the PCM switch 101) and the inductor 201 (a type of the inductor 200) are electrically connected to each other. That is, the PCM switch 301 and the inductor 201 are connected to at least one of the same nodes N31, N32, and could be considered to have at least one same equivalent endpoint. The pattern of the inductor 201 could be adjusted according to application requirement and is not limited in the disclosure.

In the embodiment, the PCM switch 301 and the inductor 201 are electrically connected in parallel. That is, two opposite terminals both of the PCM switch 301 and the inductor 201 are connected to the corresponding same nodes N31, N32 respectively. Additionally, a current through the inductor 201 or the voltage between the two nodes could be adjusted accordingly by adjusting the state of the PCM switch 301.

In an embodiment, the inductor 201 is applied for a transmitting antenna, a bandpass filter (BPF), an electrical transformer, etc. For example, two nodes N31, N32 could be applied to have different electrical potentials, to enable the inductor 201 to have a corresponding application.

In an embodiment, if there is an electrically potential difference between the two nodes N31, N32, and if the PCM switch 301 is in an “on” state, a corresponding current flowing through the PCM switch 301 could be higher than a corresponding current flowing through the inductor 201; for example, the current between the two nodes N31, N32 will hardly flow through the inductor 201 and will even be almost zero.

In an embodiment, if there is an electrically potential difference between the two nodes N31, N32, and if the PCM switch 301 is in an “off” state, a corresponding current flowing through the PCM switch 301 could be lower than a corresponding current flowing through the inductor 201; for example, the current between the two nodes N31, N32 will almost always flow through the inductor 201.

In an embodiment, the inductor 201 is applied for a receiving antenna, an electrical transformer. etc. For example, the inductor 201 could generate a corresponding induced current, to enable a corresponding application.

In an embodiment, if the PCM switch 301 is in an “on” state, even if the inductor 201 generates a corresponding induced current, most of the induced current will still flow through the PCM switch 301.

In an embodiment, if the PCM switch 301 is in an “off” state, then the induced current generated by the inductor 201 may flow through the nodes N31, N32.

In an embodiment, the inductor 201 and the circuit 151 are structurally different portions of a same conductive layer, but the disclosure is not limited thereto.

In an embodiment, the inductor 201 and a corresponding circuit 151 could be electrically connected to each other by one or more corresponding connector (e.g., a connecting circuit 153 153, and/or one or more conductive vias 154). In an embodiment, the connecting circuit 153 and the heat dissipation element 170 are structurally different portions of a same conductive layer, but the disclosure is not limited thereto. In an embodiment not shown, the connecting circuit 153 and the resistive heating element 130 may be structurally different portions of a same conductive layer, but the disclosure is not limited thereto.

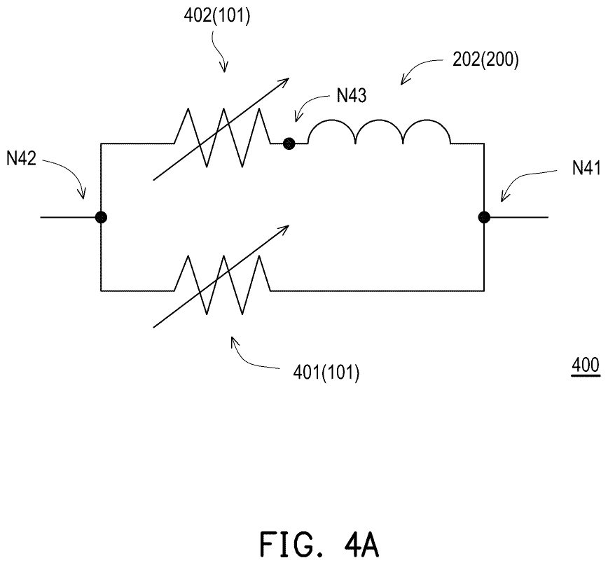

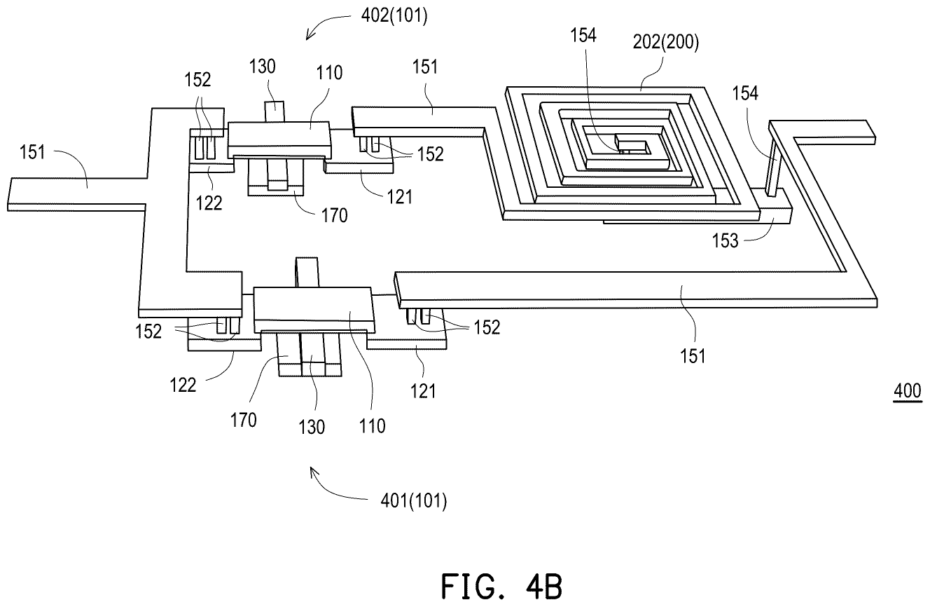

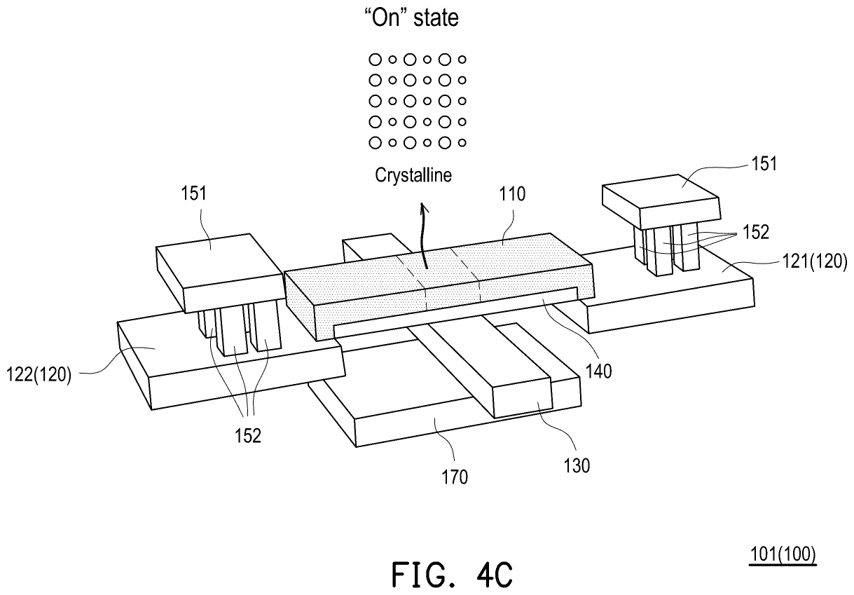

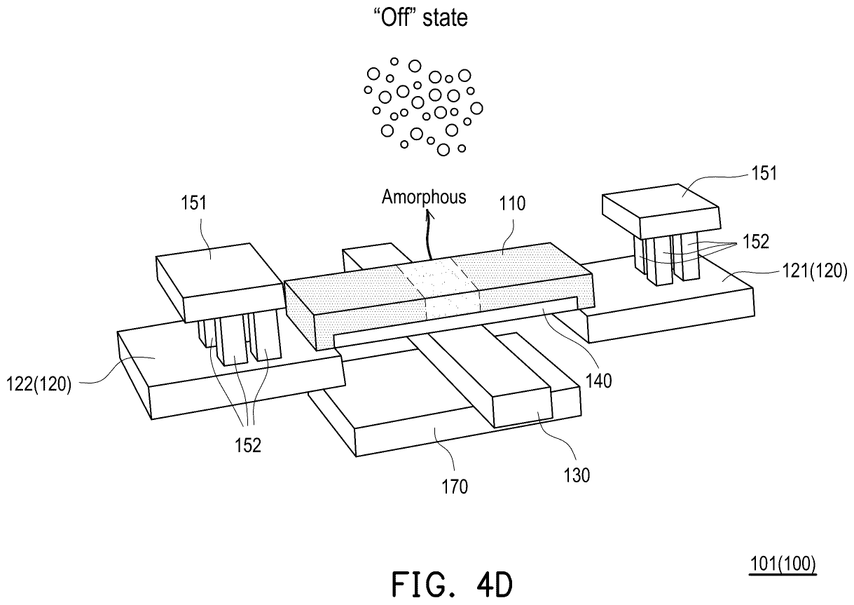

FIG. 4A illustrates a portion of a circuit diagram of an electronic component, in accordance with an embodiment of the disclosure. FIGS. 4B, 4C and 4D illustrate a portion of perspective structure views of an electronic component, in accordance with an embodiment of the disclosure. For example, the structure as shown in FIG. 4B may have an equivalent circuit as shown in FIG. 4A, and/or the circuit as shown in FIG. 4A may have a corresponding structure as shown in FIG. 4B. For example, FIG. 4C illustrates a portion of perspective structure view of an electronic component 400 as shown in FIG. 4B corresponding to a PCM switch 101 in an “on” state. For example, FIG. 4D illustrates a portion of perspective structure view of an electronic component 400 as shown in FIG. 4B corresponding to a PCM switch 101 in an “off” state. As such, for the purpose of simplicity and/or clarity, the electronic components as shown in FIGS. 4A to 4D are labeled with a same symbol.

As shown in FIGS. 4A and 4B, the electronic component 400 includes at least one PCM switch 101 (e.g., the PCM switch 401 and the PCM switch 402) and at least one an inductor 200 (e.g., the inductor 202; a type of a passive device). The PCM switch 401 (a type of the PCM switch 101) and the inductor 202 (a type of the inductor 200) are electrically connected to each other. That is, the PCM switch 101 and the inductor 202 are connected to at least one of the same nodes (the node N43), and could be considered to have at least one same equivalent endpoint. The PCM switch 402 (a type of the PCM switch 101) and the inductor 202 (a type of the inductor 200) are electrically connected to each other. That is, the PCM switch 101 and the inductor 202 are connected to at least one of the same nodes (the node N41), and could be considered to have at least one same equivalent endpoint.

In the embodiment, the PCM switch 402 and the inductor 202 are electrically connected in series. That is, the PCM switch 402 and inductor 202 could have the same current flowing therethrough.

In an embodiment, if the PCM switch 402 is in an “on” state (e.g., as shown in FIG. 4C), the inductor 202 could be enabled or disabled according to an application requirement.

In an embodiment, if the PCM switch 402 is in an “off” state (e.g., as shown in FIG. 4D), the inductor 202 could be disabled for a corresponding application. That is, the function of the inductor 202 may be blocked. It is worth noting that, as the PCM switch 101 as shown in FIG. 4D for example, as long as a portion of the phase change material 110 in the PCM switch 101 has an amorphous phase that completely crosses the direction of current flow, it is enough for the PCM switch 101 to be in an “off” state. That is, when the PCM switch 101 is in the “off” state, it is not limited that the entire phase change material 110 has an amorphous phase. Additionally, the amorphous phase of the phase change material 110 as shown in FIG. 4D is illustrated for example. For example, there may be a gradual phase change between the amorphous phase and the crystalline phase. That is, there may not be a clear interface between the amorphous and crystalline phases; and/or, there may be a region that has both amorphous and crystalline phases.

In an embodiment, if the PCM switch 401 is in an “on” state, the PCM switch 401 as shown in FIGS. 4A and/or 4B could be applied as described corresponding to the PCM switch 301 as shown in FIGS. 3A and/or 3B, and descriptions are omitted for simplicity and/or clarity.

In an embodiment, the resistive heating element 130 of the PCM switch 401 and the resistive heating element 130 of the PCM switch 402 are structurally and/or electrically separated. That is, the PCM switch 401 and the PCM switch 402 could be controlled independently, individually, and/or separately.

In an embodiment, through an appropriate circuit design, the states of the two PCM switches 401, 402 could be linked but in opposite states, while the electronic component 400 is enable. For example, the PCM switch 401 is in an “on” state and the PCM switch 402 is in an “off” state; either or, the PCM switch 401 is in an “off” state and the PCM switch 402 is in an “on” state. As such, an enabling quality of the inductor 202 could be further improved.

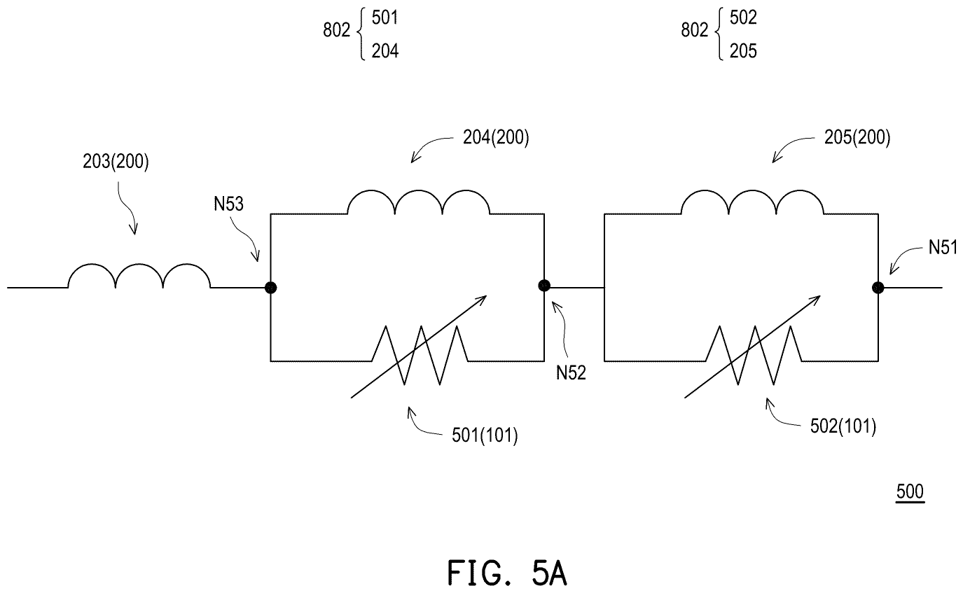

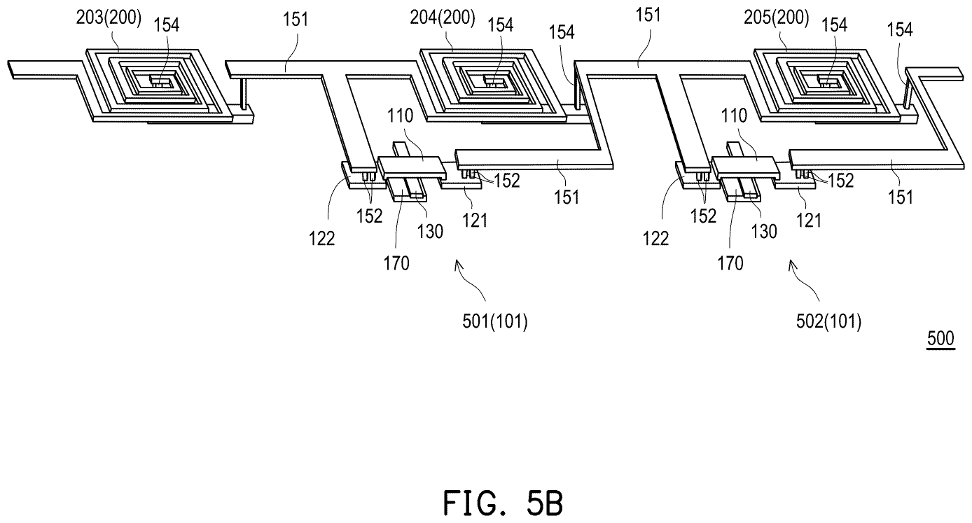

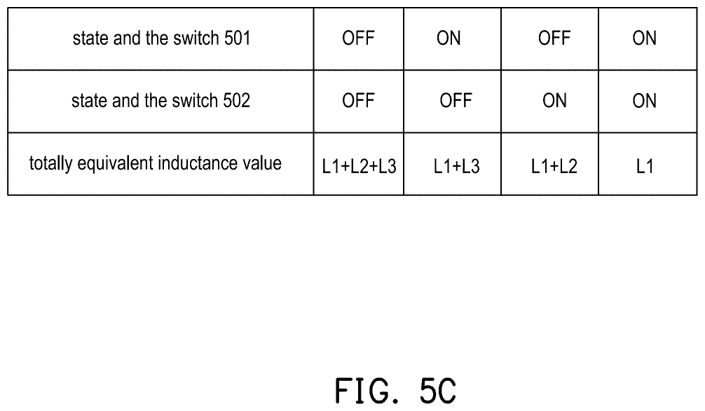

FIG. 5A illustrates a portion of a circuit diagram of an electronic component, in accordance with an embodiment of the disclosure. FIG. 5B illustrates a portion of perspective structure view of an electronic component, in accordance with an embodiment of the disclosure. For example, the structure as shown in FIG. 5B may have an equivalent circuit as shown in FIG. 5A, and/or the circuit as shown in FIG. 5A may have a corresponding structure as shown in FIG. 5B. As such, for the purpose of simplicity and/or clarity, the electronic components as shown in FIGS. 5A and 5B are labeled with a same symbol. FIG. 5C illustrates an operation diagram of an electronic component, in accordance with an embodiment of the disclosure. For example, an operation mode of the electronic components as shown in FIGS. 5A and/or 5B and the corresponding results could be as shown in FIG. 5C.

As shown in FIGS. 5A and 5B, the electronic component 500 includes at least one PCM switch 101 (e.g., a PCM switch 501 and a PCM switch 502) and at least one an inductor 200 (e.g., an inductor 203, an inductor 204, and an inductor 205; a type of a passive device). At least one PCM switch 101 and at least one inductor 200 are electrically connected to each other.

In the embodiment, the PCM switch 501 (a type of the PCM switch 101) and the inductor 204 (a type of the inductor 200) electrically connected in parallel could be regarded as a selectively enabled inductor device 801, and the PCM switch 502 (a type of the PCM switch 101) and the inductor 205 (a type of the inductor 200) electrically connected in parallel could be regarded as a selectively enabled inductor device 802. The inductor 203 (a type of the inductor 200), the selectively enabled inductor device 801, and the selectively enabled inductor device 802 are sequentially configured according to a corresponding current flow and are electrically connected in series.

In the embodiment, regarding to the selectively enabled inductor device 801, the PCM switch 501 as shown in FIGS. 5A and/or 5B could be applied as described corresponding to the PCM switch 301 as shown in FIGS. 3A and/or 3B, and descriptions are omitted for simplicity and/or clarity. Additionally, regarding to the selectively enabled inductor device 802, the PCM switch 502 as shown in FIGS. 5A and/or 5B could be applied as described corresponding to the PCM switch 301 as shown in FIGS. 3A and/or 3B, and descriptions are omitted for simplicity and/or clarity.

For example, as shown in FIG. 5C, if the PCM switch 501 and the PCM switch 502 are both in an “off” state, a totally equivalent inductance value of the electronic component 500 is substantially (e.g., ignore or do not consider the mutual coupling of magnetic fields between individual inductors) a sum of the inductance value (L1) of the inductor 203, the inductance value (L2) of the inductor 204, and the inductance value (L3) of the inductor 205.

For example, as shown in FIG. 5C, if the PCM switch 501 is in an “on” state and the PCM switch 502 is in an “off” state, a totally equivalent inductance value of the electronic component 500 is substantially (e.g., ignore or do not consider the mutual coupling of magnetic fields between individual inductors) a sum of the inductance value (L1) of the inductor 203 and the inductance value (L3) of the inductor 205.

For example, as shown in FIG. 5C, if the PCM switch 501 is in an “off” state and the PCM switch 502 is in an “on” state, a totally equivalent inductance value of the electronic component 500 is substantially (e.g., ignore or do not consider the mutual coupling of magnetic fields between individual inductors) a sum of the inductance value (L1) of the inductor 203 and the inductance value (L2) of the inductor 205.

For example, as shown in FIG. 5C, if the PCM switch 501 and the PCM switch 502 are both in an “on” state, a totally equivalent inductance value of the electronic component 500 is substantially the same or similar to the inductance value (L1) of the inductor 203.

At least according to the above-mentioned structure and/or method, the electronic component 500 could have different or selectable equivalent inductance values according to the state (e.g., “on” state or “off” state) of the corresponding one or more PCM switches 101.

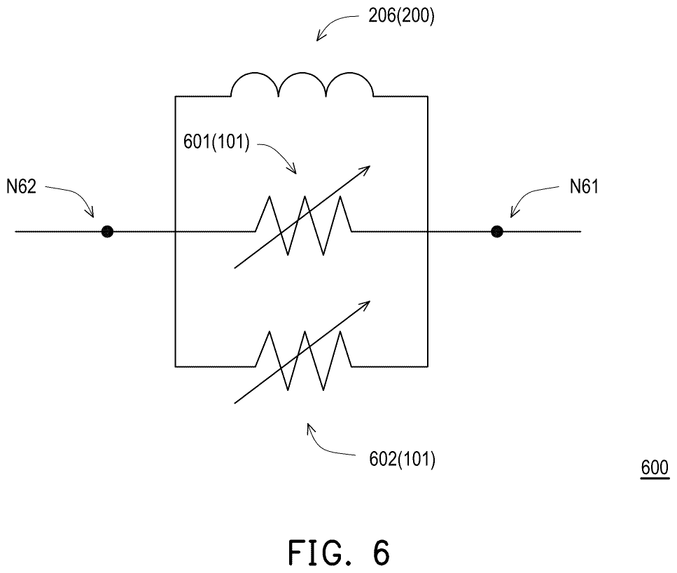

FIG. 6 illustrates a portion of a circuit diagram of an electronic component, in accordance with an embodiment of the disclosure.

As shown in FIG. 6, the electronic component 600 includes at least one PCM switch 101 (e.g., the PCM switch 601 and the PCM switch 602) and at least one an inductor 200 (e.g., the inductor 206; a type of a passive device). In the embodiment, the PCM switch 601 (a type of the PCM switch 101), the PCM switch 602 (a type of the PCM switch 101), and the inductor 206 (a type of the inductor 200) are electrically connected in parallel. That is, two opposite terminals all of the PCM switch 601, the PCM switch 602, and the inductor 206 are connected to the corresponding same nodes N61, N62 respectively.

A phase change material (e.g., the 110 as shown in FIGS. 2A, 2B, 2C or similar drawings) may be failed or aged after multiple heating cycles, that is, the phase thereof cannot be changed between amorphous or crystalline phases through heating. When a phase change material is failed or aged after multiple heating cycles, it typically becomes “stuck” or “trapped” in one phase and can no longer switch between the amorphous and crystalline phases. The failed or aged PCM is usually found in the amorphous phase. That is because the amorphous phase tends to have a higher defect density accompanied by a higher band gap, and these defects may cause the phase change irreversible.

In the embodiment, the PCM switch 601 and the PCM switch 602 are electrically connected in parallel. The PCM switch 601 and the PCM switch 602 may be used interchangeably; or, each PCM switch 601 may be a repair PCM switch 602 of each other.

The present disclosure provides various embodiments of radio frequency (RF) switching circuits using semiconductor manufacturing techniques involving phase-change material (PCM). PCM changes its electrical characteristics (e.g., resistance, etc.) in response to changing external conditions, such as temperature. The example PCM circuits described herein utilize a heater material that is formed adjacent to a PCM material, to form a high-frequency PCM switching circuit. Because the PCM has variable resistance depending on its phase, certain types of PCM can serve as electrical isolators (e.g., a switch “off” state) or electrical conductors (e.g., a switch “on” state). These material properties can be utilized to create various embodiments of parallel RF switching circuitry, as described herein.

In accordance with some embodiments of the present disclosure, an electronic component includes an inductor, a phase change material (PCM) switch, and a first electrically insulating layer. The PCM switch is electrically connected to the inductor. The PCM switch includes a phase change material (PCM) layer, a first electrode contacting the PCM layer, a second electrode contacting the PCM layer, and a first resistive heating element configured to heat a portion of the PCM layer. The first electrically insulating layer is disposed between and thermally coupled to the PCM layer and the first resistive heating element. In an embodiment, the first electrode, the second electrode and the first resistive heating element are different portions of a same conductive layer. In an embodiment, the electronic component further includes at least one circuit and at least one conductive via, wherein one of the first electrode and the second electrode is electrically connected to the inductor by the at least one circuit and the at least one conductive via. In an embodiment, the at least one circuit and the inductor are different portions of a same conductive layer. In an embodiment, the electronic component further includes a heat dissipation element thermally coupled to the first resistive heating element, wherein the first resistive heating element is disposed between the first electrically insulating layer and the heat dissipation element. In an embodiment, the electronic component further includes at least one circuit and at least one conductive via, wherein: one of the first electrode and the second electrode is electrically connected to the inductor by the at least one circuit and the at least one conductive via; and the at least one circuit and the heat dissipation element are different portions of a same conductive layer. In an embodiment, the at least one circuit includes a first circuit and a second circuit, and wherein: one of the first electrode and the second electrode is electrically connected to the inductor by the first circuit; another one of the first electrode and the second electrode is electrically connected to the inductor by the second circuit; the first circuit and the inductor are different portions of a same conductive layer; and the second circuit and the heat dissipation element are different portions of another same conductive layer. In an embodiment, the electronic component further includes a second electrically insulating layer disposed between the first electrode and the second electrode, between the first electrode and the first resistive heating element, and/or between the second electrode and the first resistive heating element, wherein a thermal conductivity of the first electrically insulating layer is higher than a thermal conductivity of the second electrically insulating layer. In an embodiment, the electronic component further includes a second resistive heating element configured to heat a portion of the PCM layer, and a third electrically insulating layer disposed between and thermally coupled to the PCM layer and the second resistive heating element.

In accordance with some embodiments of the present disclosure, a phase change material (PCM) radio-frequency (RF) circuit includes a phase change material (PCM) switch and a first inductor electrically connected to each other between a first node and a second node, wherein when the PCM RF circuit is activated, an enablement of the first inductor is depended on a state of the PCM switch; and wherein the PCM switch has an “on” state allowing current to flow therethrough, either or an “off” state blocking current to flow therethrough. In an embodiment, the PCM switch comprises a phase change material (PCM) layer, wherein the PCM layer has a crystalline phase when the PCM switch has the “on” state, either or an amorphous phase when the PCM switch has the “off” state. In an embodiment, a reversible transition between the crystalline phase and the amorphous phase is induced by an enablement of a resistive heating element. In an embodiment, wherein the PCM switch and the first inductor are electrically connected in parallel. In an embodiment, the PCM RF circuit further includes a second inductor electrically connected to the PCM switch and the first inductor in series respectively. In an embodiment, the PCM switch and the first inductor are electrically connected in series.

In accordance with some embodiments of the present disclosure, an electronic component includes a passive device, at least one circuit, at least one conductive via, a phase change material (PCM) switch, and an electrically insulating layer. The PCM switch is electrically connected to the passive device by the at least one circuit and the at least one conductive via. The PCM switch includes a phase change material (PCM) layer, a first electrode contacting the PCM layer, a second electrode contacting the PCM layer, a resistive heating element, and a heat dissipation element. The resistive heating element is configured to heat a portion of the PCM layer. The heat dissipation element is thermally coupled to the resistive heating element. The electrically insulating layer is disposed between and thermally coupled to the PCM layer and the resistive heating element. The resistive heating element is disposed between the electrically insulating layer and the heat dissipation element. In an embodiment, a portion of the passive device and the at least one circuit are different portions of a same conductive layer. In an embodiment, the heat dissipation element and the at least one circuit are different portions of a same conductive layer. In an embodiment, the first electrode, the second electrode, and the resistive heating element are different portions of a same conductive layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An electronic component, comprising:
an inductor; and
a phase change material (PCM) switch, electrically connected to the inductor, wherein the PCM switch comprises:
a phase change material (PCM) layer;
a first electrode, contacting the PCM layer;
a second electrode, contacting the PCM layer; and
a first resistive heating element, configured to heat a portion of the PCM layer; and
a first electrically insulating layer, disposed between and thermally coupled to the PCM layer and the first resistive heating element.

2. The electronic component of claim 1, wherein the first electrode, the second electrode and the first resistive heating element are different portions of a same conductive layer.

3. The electronic component of claim 1, further comprising:
at least one circuit; and
at least one conductive via, wherein:
one of the first electrode and the second electrode is electrically connected to the inductor by the at least one circuit and the at least one conductive via.

4. The electronic component of claim 1, wherein the at least one circuit and the inductor are different portions of a same conductive layer.

5. The electronic component of claim 1, further comprising:
a heat dissipation element, thermally coupled to the first resistive heating element, wherein the first resistive heating element is disposed between the first electrically insulating layer and the heat dissipation element.

6. The electronic component of claim 5, further comprising:
at least one circuit; and
at least one conductive via, wherein:
one of the first electrode and the second electrode is electrically connected to the inductor by the at least one circuit and the at least one conductive via; and
the at least one circuit and the heat dissipation element are different portions of a same conductive layer.

7. The electronic component of claim 5, wherein the at least one circuit comprises a first circuit and a second circuit, and wherein:
one of the first electrode and the second electrode is electrically connected to the inductor by the first circuit;
another one of the first electrode and the second electrode is electrically connected to the inductor by the second circuit;
the first circuit and the inductor are different portions of a same conductive layer; and
the second circuit and the heat dissipation element are different portions of another same conductive layer.

8. The electronic component of claim 1, wherein the PCM layer further laterally covers the first electrically insulating layer.

9. The electronic component of claim 1, further comprising:
a second electrically insulating layer, disposed between the first electrode and the second electrode, between the first electrode and the first resistive heating element, and/or between the second electrode and the first resistive heating element, wherein a thermal conductivity of the first electrically insulating layer is higher than a thermal conductivity of the second electrically insulating layer.

10. The electronic component of claim 1, further comprising:
a second resistive heating element, configured to heat a portion of the PCM layer; and
a third electrically insulating layer, disposed between and thermally coupled to the PCM layer and the second resistive heating element.

11. A phase change material (PCM) radio-frequency (RF) circuit, comprising:
a phase change material (PCM) switch and a first inductor electrically connected to each other between a first node and a second node,
wherein when the PCM RF circuit is activated, an enablement of the first inductor is depended on a state of the PCM switch; and
wherein the PCM switch has an “on” state allowing current to flow therethrough, either or an “off” state blocking current to flow therethrough.

12. The PCM RF circuit of claim 11, wherein the PCM switch comprises a phase change material (PCM) layer,
wherein the PCM layer has a crystalline phase when the PCM switch has the “on” state, either or an amorphous phase when the PCM switch has the “off” state.

13. The PCM RF circuit of claim 12, wherein a reversible transition between the crystalline phase and the amorphous phase is induced by an enablement of a resistive heating element.

14. The PCM RF circuit of claim 11, wherein the PCM switch and the first inductor are electrically connected in parallel.

15. The PCM RF circuit of claim 12, further comprising:
a second inductor, electrically connected to the PCM switch and the first inductor in series respectively.

16. The PCM RF circuit of claim 11, wherein the PCM switch and the first inductor are electrically connected in series.

17. An electronic component, comprising:
a passive device;
at least one circuit;
at least one conductive via;
a phase change material (PCM) switch, electrically connected to the passive device by the at least one circuit and the at least one conductive via, wherein the PCM switch comprises:
a phase change material (PCM) layer;
a first electrode contacting the PCM layer;
a second electrode contacting the PCM layer;
a resistive heating element, configured to heat a portion of the PCM layer; and
a heat dissipation element, thermally coupled to the resistive heating element; and
an electrically insulating layer, disposed between and thermally coupled to the PCM layer and the resistive heating element, wherein the resistive heating element is disposed between the electrically insulating layer and the heat dissipation element.

18. The electronic component of claim 17, wherein a portion of the passive device and the at l east one circuit are different portions of a same conductive layer.

19. The electronic component of claim 17, wherein the heat dissipation element and the at least one circuit are different portions of a same conductive layer.

20. The electronic component of claim 17, wherein the first electrode, the second electrode, and the resistive heating element are different portions of a same conductive layer.
